(19) United States
(12) Patent Application Publication
(10) Pub. No.: US 2009/0032289 A1
(43) Pub. Date: Feb. 5, 2009

(54) Circuit board having two or more planar sections

(75) Inventors: Ian Timms, Yateley (GB); Tomi Sakain Kanninen, Salo (FI)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(73) Assignee: Nokia Corporation

(21) Appl. No.: 11/888,666

(22) Filed: Jul. 31, 2007

(51) Int. Cl. H05K 1/02; H05K 3/02

(52) U.S. Cl. 174/254; 29/832

(57) ABSTRACT

A single circuit board has at least two planar sections and a bent section linking the planar sections. The circuit board has a circuit layer disposed on an insulating layer to provide routings and electrical connections to the electronic components on the two planar sections. The circuit layer has at least one circuit section on each of the two planer sections and one circuit section on the bent section. The single circuit board can have a ground plane or a second circuit layer disposed on the insulting layer on the opposite side of the circuit layer. The planar sections can be located on the same plane or on different planes. The multi-section circuit board can be made from a single-plane circuit board by using a mechanical tool to bend the board into shape.

### FIELD OF THE INVENTION

The present invention relates generally to a printed wire board (PWB) or a printed circuit board (PCB) and, more specifically, to an electronic circuitry in an electronic device that has electronic components to be supported in two or more planes.

### BACKGROUND OF THE INVENTION

In an electronic device that has electronic components to be mounted or supported in two or more planes, two or more circuit boards, such as PWBs or PCBs located on different planes, are used to support those electronic components. Typically, each of the individual circuit boards will have one or more connector sockets so that a connector, such as a flexible connector, or flex, is used to provide an electrical linkage between two connector sockets in different circuit boards. The use of connector sockets and connectors increase the component counts and, therefore, the production cost. The connections between circuit boards are also the weak points in protecting the electronic components and signals from electrical sparks and magnetic radiation.

It would be advantageous and desirable to provide such a circuit board without the use of connectors.

### SUMMARY OF THE INVENTION

The objective of the present invention is to solve a problem of electrically connecting two separate circuit boards without additional components. To achieve the above objective, the present invention provides a single circuit board that has two or more substantially planar sections located on the same plane or on different planes. The circuit board has one or more bent sections linking the different planar sections. The shape of the multi-plane circuit board can be the result of mechanical bending after the circuit board is made.

Thus, the first aspect of the present invention is a circuit board which comprises:

at least one insulating layer, and

at least one routing or circuit layer made of an electrically conducting material disposed on said at least one insulating layer, wherein the circuit board has at least two planar sections linked by a bent section and wherein the routing or circuit layer comprises a plurality of routing or circuit sections, and each of said at least two planar sections and the bent section comprises one routing or circuit section.

The circuit board may have one or more ground planes, one or more other routing or circuit layers made of an electrically conducting material and one or more insulating layers, wherein two adjacent electrically conducting layers are separated by one insulating layer.

The second aspect of the present invention is a method of making a circuit board. The method comprises:

providing at least one insulating layer;

disposing a routing or circuit layer at least on one side of the insulating layer for forming a single-plane circuit board; and

shaping the single-plane circuit board into a plurality of planar sections and one or more bent sections located between the planar sections, wherein the routing layer comprises a plurality of routing or circuit sections, and each of at least two of the planar sections and the bent section therebetween comprises one routing or circuit section.

The third aspect of the present invention is an electronic device having a circuit board, according to one embodiment of the present invention.

### BRIEF DESCRIPTION OF THE DRAWINGS

FIG. 1a shows the cross sectional view of the multi-plane circuit board, according to one embodiment of the present invention.

FIG. 1b shows the multi-plane circuit board having a plurality of electronic components disposed thereon.

FIG. 2 shows an exemplary layer structure of the multi-plane circuit board.

FIG. 3a shows a method of making a multi-plane circuit board, according to one embodiment of the present invention.

FIG. 3b shows a method of making a plurality of multi-plane circuit boards, according to one embodiment of the present invention.

FIG. 4 shows a multi-plane circuit board, according to a different embodiment of the present invention.

FIG. 5 shows a multi-plane circuit board, according to yet another embodiment of the present invention.

FIG. 6 shows a circuit board having a plurality of planar sections linked by a bent section, wherein the planar sections can be located on the same plane or on different planes, according to one embodiment of the present invention.

FIG. 7 shows an electronic device having a multi-plane circuit board, according to one embodiment of the present invention.

### DETAILED DESCRIPTION OF THE INVENTION

In an electronic device that has electronic components to be mounted in two or more planes, two or more circuit boards, such as printed wire boards (PWBs) and printed circuit boards (PCBs) are typically used. These circuit boards are linked by one or more connectors so that electrical signals and power can be conveyed between the separated circuit boards. The connecting components, including connector sockets and flexible connectors or the like are usually the sources of reliability weak points. Because of the lack of proper grounding or shielding on the signal lines in the connecting components, protection on the electronic components against electrical sparks and electromagnetic radiation may not be adequate.

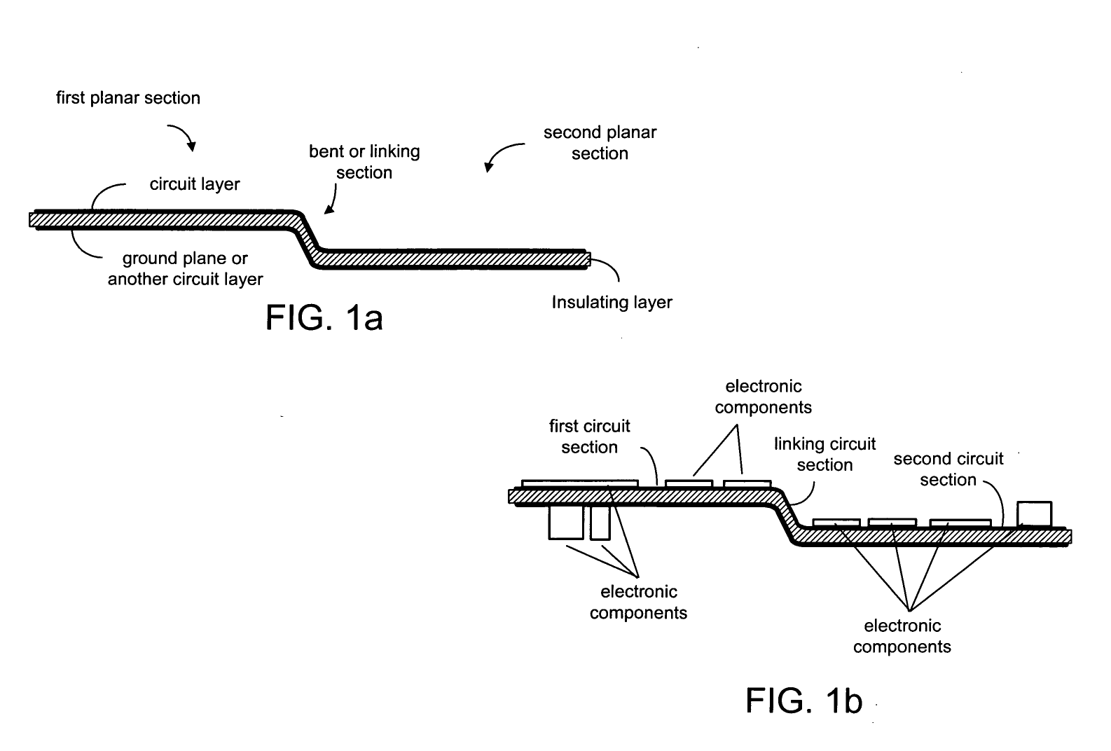

The present invention provides a single circuit board which is shaped to form different sections, including two or more planar sections located on the same plane or on different planes. For example, the single circuit board can be made of a single printed wire board or printed circuit board with a ground plane on one side and routings on the other side of the board. A mechanical tool is then used to press the single-plane circuit board into different planar sections linked by one or more bent sections, as shown in FIG. 1a. As such, separate connecting components are not required to provide electrical connections between two planar sections.

After the single circuit board with different planar sections is made, electronic components can then be disposed on one or both sides of the circuit board, as shown in FIG. 1b. As shown in FIG. 1b, the routing or circuit layer on the circuit board comprises a first routing or circuit section located on the first planar section of the circuit board and a second routing or circuit section located on the second planar section. A linking routing or circuit section located on the bent section of the circuit board provides the necessary electrical connections between the first and second planar sections. The various routing or circuit sections are the result of the bending of one continuous routing or circuit layer along with the bending of the single circuit board itself.

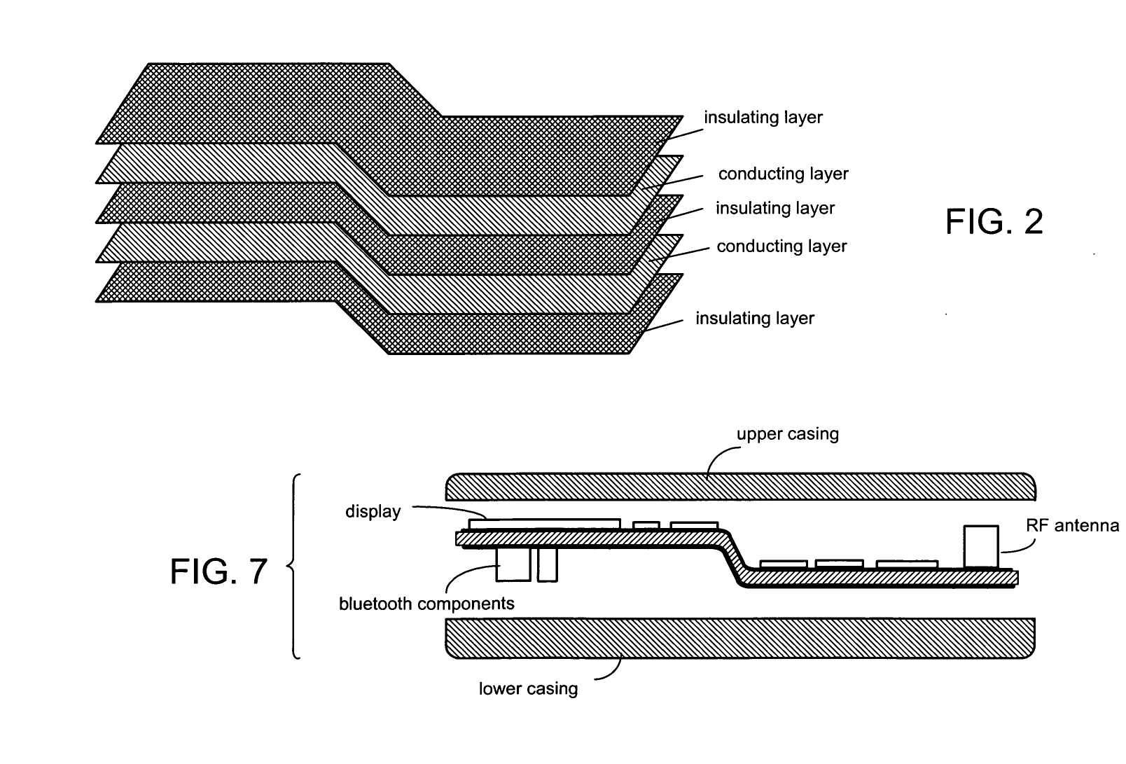

It should be noted that although there are three routing or circuit sections on the circuit board as depicted in FIG. 1b, it is possible that only one or two sections are used for connecting electronic components. For example, as depicted in FIG. 2b, there is no electronic components mounted on the linking section. In that case, the linking routing section may have only conductive tracks or wires for electrically linking the first and second routing or circuit sections. It is also possible that the routing or circuit section on the first planar section actually has a circuit layout for connecting electronic components and the other two routing sections have only conductive tracks or wires. Likewise, the ground plane or routing layer on the lower surface of the circuit board as depicted in FIG. 1a may have a circuit layout only on the first planar section, on both the first and second planar sections. Thus, the conductive layer on the linking section on the lower surface of the circuit board may only have conductive tracks or wires, and not a circuit layout.

Typically, a PWB is made of a number of layers, as shown in FIG. 2. For example, a PWB can be made of two electrically conducting layers and three insulating layers. One electrically conducting layer can be used for routings and the other can be used as a ground plane, for example. The electrically conducting layers can be made of copper, for example. Both electrically conducting layers can also be used for routings. Because both routing or circuit layers are made of an electrically conducting material, one routing or circuit layer can be used as a protecting layer for the other routing or circuit layer in protecting electrical signals on the circuit board from being disturbed or interfered by external radiation.

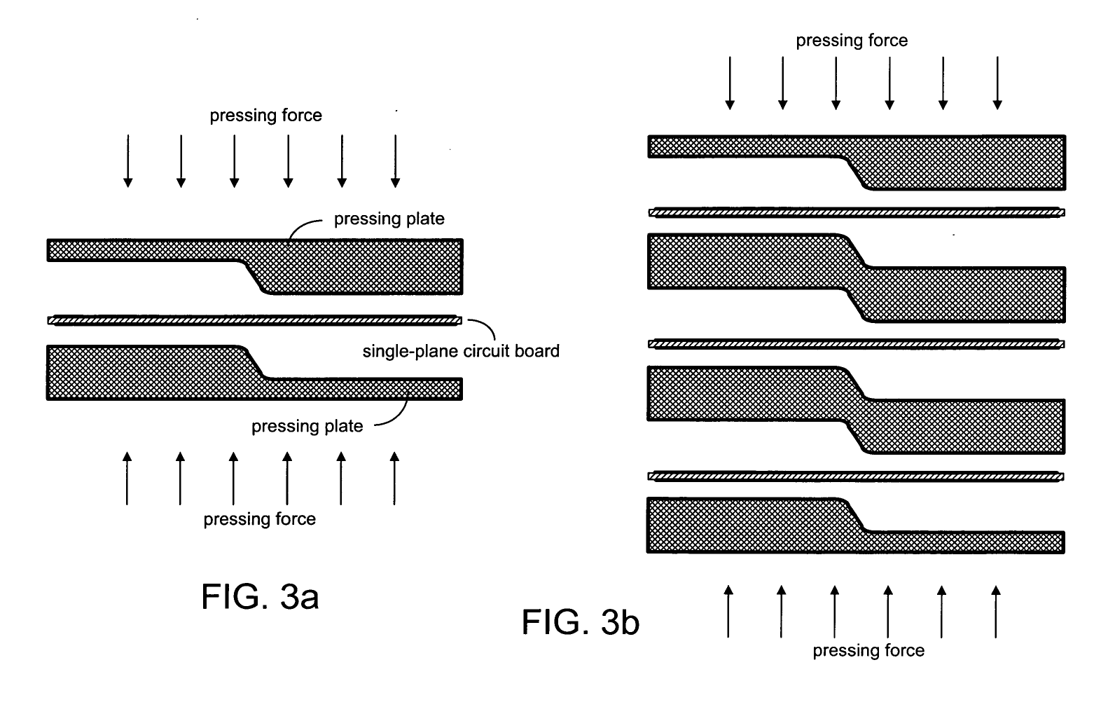

The shaping of a single-plane circuit board into a multi-plane circuit board is illustrated in FIG. 3a. As shown in FIG. 3a, the single-plane circuit board is placed between two pressing plates made of steel, for example, for pressing. After the pressing plates are pressed against each other, the single-plane circuit board will be shaped according the shape of the pressing plates, while the routings and other electrically conducting surfaces are kept electrically intact.

The shaping of multi-plane circuit boards can be carried out using three or more pressing plates so that two or more single-plane circuit boards can be shaped simultaneously, as shown in FIG. 3b.

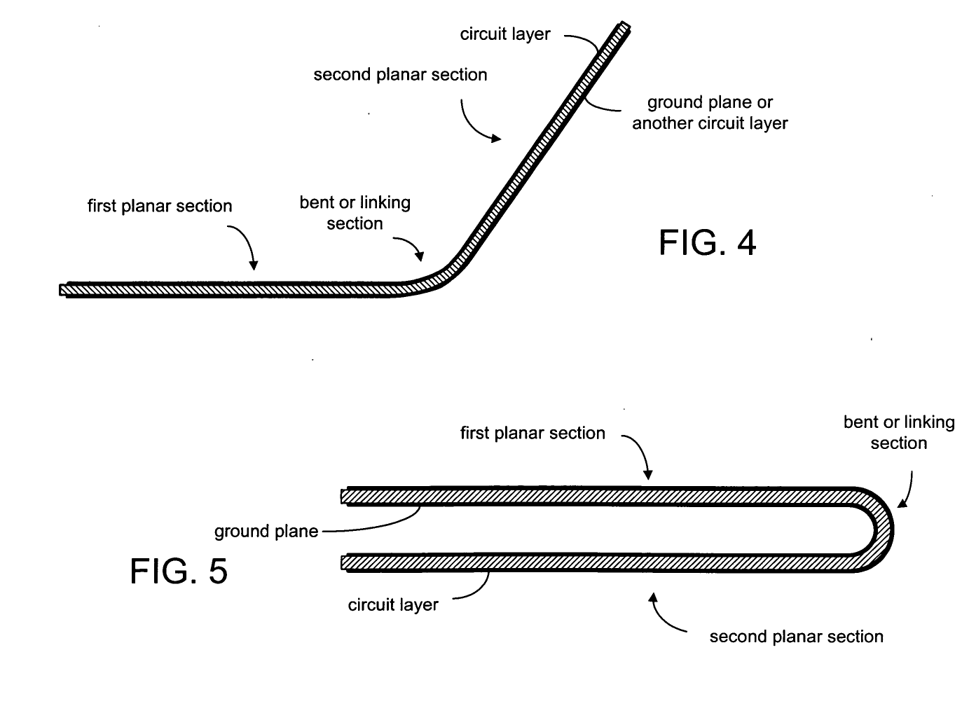

The multi-plane circuit board as shown in FIGS. 1a and 1b represents only one of the embodiments, according to the present invention. In this embodiment, the two planar sections are located on parallel planes and they are not overlapping with each other. It should be noted that, in a different embodiment, the planar sections are not located on parallel planes, as shown in FIG. 4. In yet another embodiment, the planar sections may have a partially or entirely overlapped area, as shown in FIG. 5.

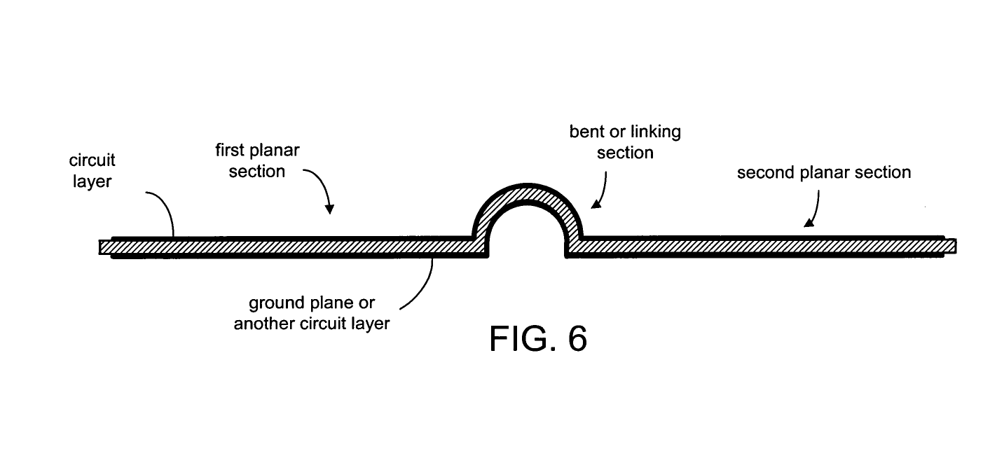

In another embodiment of the present invention, as shown in FIG. 6, the planar sections can be located on the same plane or on different planes.

FIG. 7 is a schematic representation of an electronic device having a multi-plane circuit board, according to one embodiment of the present invention. As shown in FIG. 7, the electronic device has an upper casing and a lower casing to house the multi-plane circuit board and the electronic components. One of the electronic components can be an RF antenna and one can be a Bluetooth antenna, for example. The electronic device can be a mobile terminal, for example.

In sum, the present invention provides a single circuit board which comprises two or more planar sections electrically and structurally linked by one or more bent or linking sections. The planar sections can be located on the same plane or on different planes. The planes can be parallel to each other or form a non-zero angle with each other. At least one of the planar sections and the linking section are angularly disposed relative to one another. The circuit board has at least one routing or circuit layer made of electrically conductive material disposed on a common insulating layer. The routing or circuit layer has a number of routing or circuit layer sections to provide electrical connections between various electronic components mounted on different planar sections of the circuit board. Thus, one of the routing or circuit layer sections is located in the bent section of the circuit board to provide electrical connections between two adjacent planar sections of the circuit board.

The circuit board also has at least one common insulating layer or electrically non-conducting substrate for supporting the routing layer. The circuit board may have a ground plane, made of an electrically conducting material, located on a different side of the common insulating layer. In addition, the circuit board may have more than one common insulating layer and two or more routing or circuit layers separated by insulating layers. Each of the routing or circuit layers is made of an electrically conducting material, such as copper.

The various layers disposed on the two sides of the common insulating layer can be arranged differently. For example, when one circuit layer is disposed on one side of the common insulating layer, the circuit layer may have a plurality of circuit layer sections such that each of the planar sections and the linking section has one circuit layer section. In one embodiment of the present invention, a part of the circuit layer is disposed on the first side of the linking section and a conductive track is located on the second side of the linking section. In another embodiment of the present invention, the circuit board has a conductive track section located on the first side of the linking section and a ground plane located on the second side. In a different embodiment, the circuit board has a first conductive track section located on the first side of the linking section and a second conductive track section located on the second side.

The circuit layer can be a printed wire layer.

While there are many ways in making a circuit board with a plurality of planar sections, according to different embodiment of the present invention, one of the methods comprises the following steps: providing at least one insulating layer, disposing at least one routing layer for forming a substantially single-plane circuit board, and shaping the substantially single-plane circuit board into at least two planar sections. The planar sections can be located on the same plane or on different planes, wherein two adjacent planar sections are electrically and structurally connected together by a bent or linking section. At least one of the planar sections and the linking section are angularly disposed relative to one another. Furthermore, one or more additional circuit layers or grounding layers made of an electrically conducting material may be provided on the single-plane circuit board, wherein two adjacent electrically conducting layers are separated by at least one insulating layer. The single-circuit board, according to various embodiments of the present invention has a number of advantages over the conventional multi-board linked by a flexible connector. One major advantage is that, in the single circuit board of the present invention, the circuit layer is continuous for providing electrical connections to electronic components disposed on different planar sections. As such, no discrete connection parts (including flexible connectors and sockets) are needed. Furthermore, it would be easy to provide a continuous ground plane from one planar section to another section through a linking bent section. As such, proper grounding is provided throughout various sections of the circuit board.

Thus, although the present invention has been described with respect to one or more embodiments thereof, it will be understood by those skilled in the art that the foregoing and various other changes, omissions and deviations in the form and detail thereof may be made without departing from the scope of this invention.

1. A circuit board, comprising:
a common insulating layer, and
a circuit layer disposed on the common insulating layer, wherein the circuit board has at least two planar sections linked by a linking section and wherein at least one of the planar sections and the linking section are angularly disposed relative to one another.

2. The circuit board of claim 1, wherein the planar sections are located on different planes.

3. The circuit board of claim 1, wherein the planar sections are located on a plane separated by the linking section.

4. The circuit board of claim 1, wherein the circuit layer comprises a plurality of circuit layer sections such that each of the planar sections and the linking section has one circuit layer section.

5. The circuit board of claim 1, wherein the linking section has a first side and an opposing second side, wherein a part of the circuit layer is disposed on the first side of the linking section and a conductive track is located on the second side of the linking section.

6. The circuit board of claim 1, wherein the linking section has a first side and an opposing second side, wherein the circuit board has a conductive track section located on the first side and a ground plane located on the second side.

7. The circuit board of claim 1, wherein the linking section has a first side and an opposing second side, wherein the circuit board has a first conductive track section located on the first side and a second conductive track section located on the second side.

8. The circuit board of claim 1, wherein the circuit layer is a printed wire layer.

9. The circuit board of claim 1, wherein the common insulating layer has a first side for disposing the circuit layer and an opposing second side, said circuit board further comprising:
a second insulating layer located adjacent to the second side of the common insulating layer, and
an electrically conducting layer disposed between the second insulating layer and the second side of the insulating layer.

10. The circuit board of claim 1, wherein the common insulating layer has a first side for disposing the circuit layer and an opposing second side, said circuit board further comprising
an electrically conducting layer disposed on the second side of the common insulating layer.

11. The circuit board of claim 10, wherein the electrically conducting layer comprises a second circuit layer.

12. The circuit board of claim 10, wherein the electrically conducting layer comprises a ground plane.

13. A method for producing a circuit board, comprising:
providing a common insulating layer;
disposing a circuit layer on the common insulating layer for forming a single-plane circuit board; and
shaping the single-plane circuit board into at least two planar sections and one linking section located between the planar sections, wherein at least one of the planar sections and the linking section are angularly disposed relative to one another.

14. The method of claim 13, wherein the planar sections are located on different planes.

15. The method of claim 13, wherein the insulating layer has a first side for disposing the circuit layer and an opposing second side, said method further comprising:
disposing an electrically conducting layer and then another insulating layer on the second side of the insulating layer for forming the single-plane circuit board prior to said shaping.

16. The method of claim 13, wherein the common insulating layer has a first side for disposing the circuit layer and an opposing second side, said method further comprising:
disposing an electrically conducting layer on the second side of the common insulating layer for forming the single-plane circuit board prior to said shaping.

17. The method of claim 16, wherein the electrically conducting layer comprises a ground plane.

18. The method of claim 16, wherein the electrically conducting layer comprises a second circuit layer.

19. An electronic device, comprising:
a device body;
a circuit board mounting on the device body, said circuit board comprising:
a common insulating layer, and
a circuit layer disposed on the common insulating layer, wherein the circuit board comprises at least two planar sections linked by a linking section and wherein at least one of the planar sections and the linking section are angularly disposed relative to each other; and
a plurality of electronic components mounted on the circuit board.

20. The electronic device of claim 19, wherein the planar sections are located on different planes.

21. The electronic device of claim 19, wherein the insulating layer has a first side for disposing the circuit layer and an opposing second side, said circuit board further comprising
an electrically conducting layer disposed on the second side of the insulating layer.

22. The electronic device of claim 21, wherein the electrically conducting layer comprises a second circuit layer.
